(19) United States
(12) Patent Application Publication
(10) Pub. No.: US 2020/0381338 A1
(43) Pub. Date: Dec. 3, 2020

(54) SEMICONDUCTOR DEVICE PACKAGE AND METHOD FOR MANUFACTURING THE SAME

(71) Applicant: Advanced Semiconductor Engineering, Inc., Kaohsiung (TW)

(72) Inventors: Tang-Yuan CHEN, Kaohsiung (TW); Yuan Tzuo LUO, Kaohsiung (TW); Shao-Cheng YEN, Kaohsiung (TW); Meng-Kai SHIH, Kaohsiung (TW); Chih-Pin HUNG, Kaohsiung (TW)

(73) Assignee: Advanced Semiconductor Engineering, Inc., Kaohsiung (TW)

(21) Appl. No.: 16/430,260

(22) Filed: Jun. 3, 2019

(51) Int. Cl. H01L 23/433; H01L 23/31; H01L 21/56

(52) U.S. Cl. CPC H01L 23/4334; H01L 23/498; H01L 21/56; H01L 23/3185

(57) ABSTRACT

A semiconductor device package includes a carrier, an electronic component, a package body and a ring structure. The electronic component is disposed on the carrier. The electronic component has a side surface. The package body is disposed on the carrier. The package body exposes at least a portion of the side surface of the electronic component. The ring structure is disposed on the package body and surrounds the portion of the side surface of the electronic component exposed from the package body.

### BACKGROUND

### 1. Technical Field

The present disclosure relates to a semiconductor device package, and to a semiconductor device package including a heat dissipation structure.

### 2. Description of the Related Art

The semiconductor industry has seen growth in an integration density of a variety of electronic components in some semiconductor device packages. This increased integration density often corresponds to an increased power density in the semiconductor device packages. As the power density of semiconductor device packages grows, heat dissipation can become desirable, in some implementations. Thus, it can be useful in some implementations to provide a semiconductor device package with improved thermal conductivity.

### SUMMARY

In some embodiments, a semiconductor device package includes a carrier, an electronic component, a package body and a ring structure. The electronic component is disposed on the carrier. The electronic component has a side surface. The package body is disposed on the carrier. The package body exposes at least a portion of the side surface of the electronic component. The ring structure is disposed on the package body and surrounds the portion of the side surface of the electronic component exposed from the package body

In some embodiments, a semiconductor device package includes a carrier, an electronic component, a package body, a ring structure and a heat sink. The electronic component is disposed on the carrier. The electronic component has a side surface. The package body is disposed on the carrier. The ring structure disposed on the package body and surrounds the electronic component. The heat sink is disposed on the ring structure and the electronic component.

In some embodiments, a method of manufacturing a semiconductor device package includes (a) providing a carrier; (b) disposing an electronic component on the carrier, the electronic component having a side surface; (c) forming a package body on the carrier, the package body exposing at least a portion of the side surface of the electronic component; and (d) disposing a ring structure on the package body to surround the portion of the side surface of the electronic component exposed from the package body.

### BRIEF DESCRIPTION OF THE DRAWINGS

Aspects of some embodiments of the present disclosure are best understood from the following detailed description when read with the accompanying figures. It is noted that various structures may not be drawn to scale, and dimensions of the various structures may be arbitrarily increased or reduced for clarity of discussion.

FIG. 1A is a cross-sectional view of a semiconductor device package in accordance with some embodiments of the present disclosure.

FIG. 1B is a top view of the semiconductor device package in FIG. 1A in accordance with some embodiments of the present disclosure.

FIG. 2 is a cross-sectional view of a semiconductor device package in accordance with some embodiments of the present disclosure.

FIG. 3 is a cross-sectional view of a semiconductor device package in accordance with some embodiments of the present disclosure.

FIG. 4 is a cross-sectional view of a semiconductor device package in accordance with some embodiments of the present disclosure.

FIG. 5A, FIG. 5B and FIG. 5C illustrate cross-sectional views of a semiconductor device package at various stages of fabrication, in accordance with some embodiments of the present disclosure.

### DETAILED DESCRIPTION

The following disclosure provides for many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such arrangement.

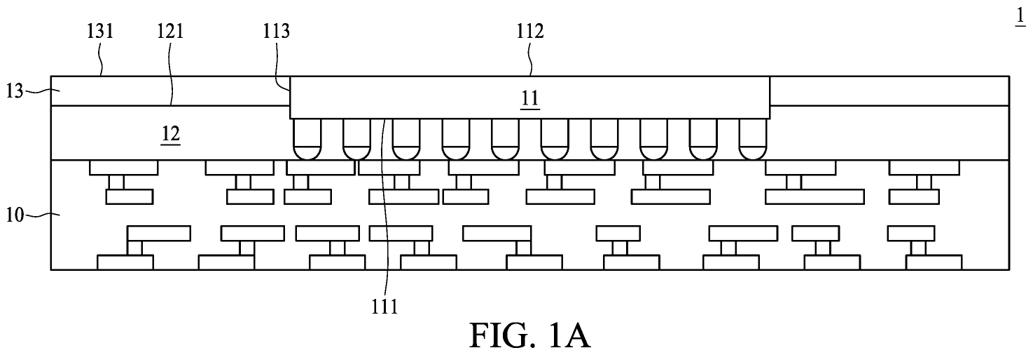

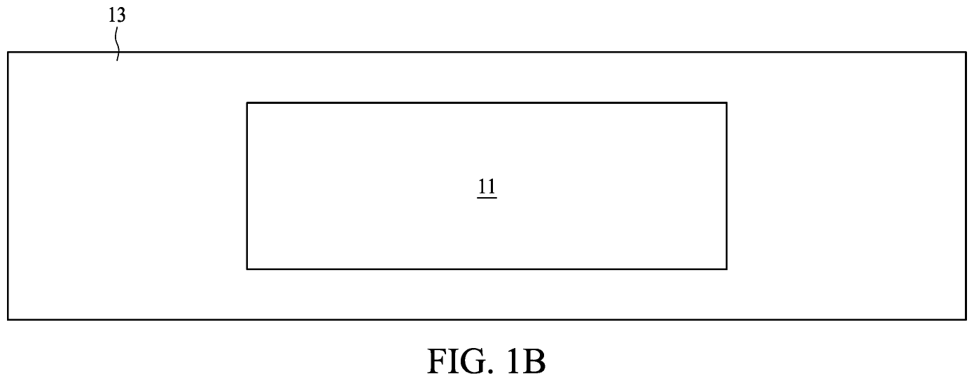

FIG. 1A is a cross-sectional view of a semiconductor device package 1 in accordance with some embodiments of the present disclosure. The semiconductor device package 1 includes a carrier 10, an electronic component 11, a package body 12 and a ring structure 13.

The carrier 10 may be, for example, a printed circuit board, such as a paper-based copper foil laminate, a composite copper foil laminate, or a polymer-impregnated glass-fiber-based copper foil laminate. The carrier 10 may include an interconnection structure, such as a redistribution layer (RDL) or a grounding element. In some embodiments, the carrier 10 includes a ceramic material or a metal plate. In some embodiments, the carrier 10 may include a substrate, such as an organic substrate or a leadframe. In some embodiments, the carrier 10 may include a two-layer substrate which includes a core layer and a conductive material and/or structure disposed on an upper surface and a bottom surface of the carrier 10. The conductive material and/or structure may include a plurality of traces.

The electronic component 11 is disposed on the carrier 10. The electronic component 11 has an active surface 111, a back surface 112 (also referred to as backside) opposite to the active surface 111 and a lateral surface 113 extending between the active surface 111 and the back surface 112. The active surface 111 of the electronic component 11 faces the carrier 10 and electrically connected to the carrier through electrical contacts (e.g., conductive bumps or copper pillars). The electronic component 11 may be a chip or a die including a semiconductor substrate, one or more integrated circuit devices and one or more overlying interconnection structures therein. The integrated circuit devices may include active devices such as transistors and/or passive devices such resistors, capacitors, inductors, or a combination thereof. The electronic component 11 may be electrically connected to the carrier 10 (e.g., to the RDL), and electrical connection may be attained by way of flip-chip, wire-bond or surface-mount technology (SMT).

The package body 12 is disposed on the carrier 10. In some embodiments, the package body 12 covers the active surface 111 and a portion of the lateral surface 113 of the electronic component 11. The package body 12 exposes the other portion of the lateral surface 113 and the back surface 112 of the electronic component 11. For example, a top surface 121 of the package body 12 is at or adjacent to the lateral surface 113 of the electronic component 11. For example, the top surface 121 of the package body 12 is not coplanar with the back surface 112 of the electronic component 11. For example, the top surface 121 of the package body 12 is lower than the back surface 112 of the electronic component 11. In other embodiments, the lateral surface 113 of the electronic component 11 is fully exposed from the package body 12 depending on different design specifications. For example, the top surface 121 of the package body 12 is substantially coplanar with the back surface 112 of the electronic component 11. In some embodiments, the package body 12 includes, for example, one or more organic materials (e.g., a molding compound, bismaleimide triazine (BT), a polyimide (PI), a polybenzoxazole (PBO), a solder resist, an Ajinomoto build-up film (ABF), a polypropylene (PP), an epoxy-based material, or a combination of two or more thereof), inorganic materials (e.g., silicon, a glass, a ceramic, a quartz, or a combination of two or more thereof), liquid-film material(s) or dry-film material(s), or a combination of two or more thereof.

The ring structure 13 is disposed on the top surface 121 of the package body 12. The ring structure 13 surrounds the lateral surface 113 of the electronic component 11 as shown in FIG. 1B, which illustrates a top view of the semiconductor device package 1 in FIG. 1A. In some embodiments, the ring structure 13 surrounds the lateral surface 113 of the electronic component 11 that exposed from the package body 12. In some embodiments, the ring structure 13 is in contact with the lateral surface 113 of the electronic component 11 that exposed from the package body 12. In some embodiments, the ring structure 13 has a surface 131 substantially coplanar with the back surface 112 of the electronic component 11. In some embodiments, the semiconductor device package 1 may include an underfill disposed between the active surface 111 of the electronic component 11 and the carrier 10, and the package body 12 covers the underfill.

In some embodiments, the ring structure 13 includes a material having a tensile strength greater than a tensile strength of the package body 12. In some embodiments, the tensile strength of the ring structure 13 is greater than 100 Mpa (e.g., 100 N/mm²). In some embodiments, the ring structure 13 includes, for example, metal (e.g., copper) or alloy. In some embodiments, an interface between the package body 12 and the ring structure 13 is located at or adjacent to the lateral surface 113 of the electronic component 11. In other embodiments, the interface between the package body 12 and the ring structure 13 may be substantially coplanar with the active surface 111 of the electronic component 11.

In some embodiments, the ring structure 13 may be or include a heat pipe or a vapor chamber. For example, the ring structure 13 may include one or more chambers formed by a conductive plate and having a plurality of wicks and fluid within the chambers. In some embodiments, the wicks may be formed of or include sintered powder, mesh, grooves, or any combination thereof. In some embodiments, the material of the fluid is selected based on the temperature at which the ring structure 13 may operate (e.g., the operating temperature). For example, the fluid is selected so that the chambers include both vapor and liquid over the operating temperature range. In some embodiments, the fluid may include, for example, water or an organic solution, such as ammonia, alcohol, ethanol or any other suitable materials.

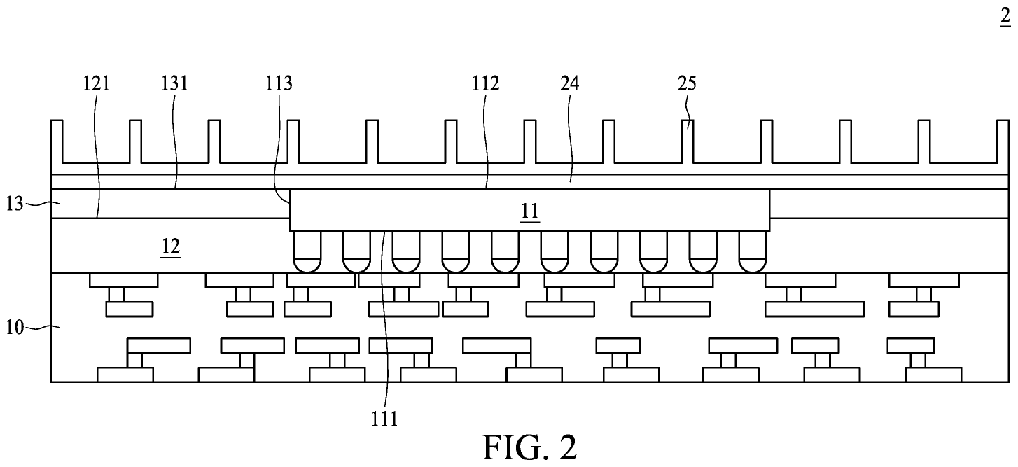

FIG. 2 illustrates a cross-sectional view of a semiconductor device package 2 in accordance with some embodiments of the present disclosure. The semiconductor device package 2 is similar to the semiconductor device package 1 in FIG. 1A except that the semiconductor device package 2 further includes a thermal interface material (TIM) 24 and a heat sink 25.

The TIM 24 is disposed on the ring structure 13 and the electronic component 11. In some embodiments, the TIM 24 contacts the surface 131 of the ring structure 13 and the back surface 112 of the electronic component 11, which can provide enhanced heat dissipation for the electronic component 11. In some embodiments, the TIM 24 can be replaced by solder or other materials suitable for heat dissipation (e.g. thermally conductive materials, such as materials including a metal). The heat sink 25 is disposed on the TIM 24 for heat dissipation.

In some embodiments, the ring structure 13 can be omitted, and the TIM 24 and the heat sink 25 are directly disposed on the back surface 112 of the electronic component 11 and the package body 12. However, because the stress generated by the heat sink 25 or TIM 24 during the thermal process is relatively large, the electronic component 11 or the package body 12 may be cracked or damaged. In accordance with the embodiment as shown in FIG. 2, the ring structure 13 is disposed on the package body 12 and the electronic component 11, and the TIM 24 and the heat sink 25 are disposed on the ring structure 13. Since the ring structure 13 is selected to include a material having a tensile strength greater than a tensile strength of the package body 12, which can prevent the electronic component 11 or the package body 12 from being cracked or damaged during the thermal process.

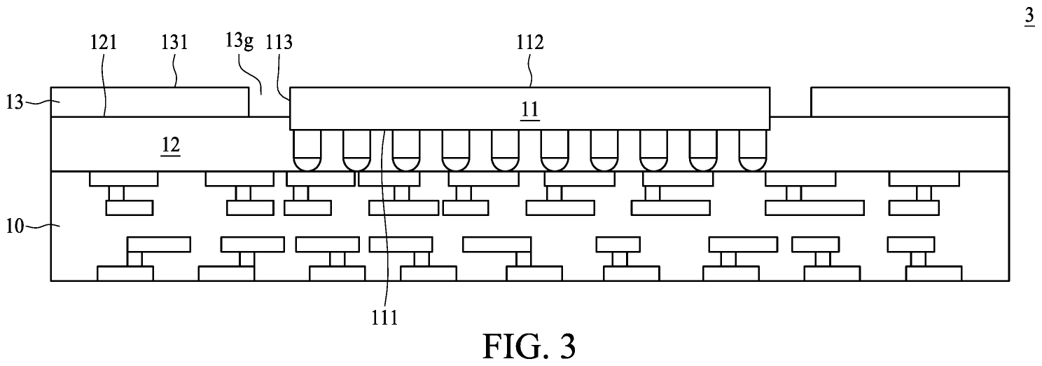

FIG. 3 illustrates a cross-sectional view of a semiconductor device package 3 in accordance with some embodiments of the present disclosure. The semiconductor device package 3 is similar to the semiconductor device package 1 in FIG. 1A except that the ring structure 13 in FIG. 3 does not contact the lateral surface 113 of the electronic component 11 that exposed from the package body 12. For example, the ring structure 13 is spaced apart from the lateral surface 113 of the electronic component 11 that exposed from the package body 12. For example, there is a gap 13g between the ring structure 13 and the lateral surface 113 of the electronic component 11 that exposed from the package body 12. The gap 13g can prevent the electronic component 11 from crack due to the compression of the ring structure 13 during the thermal process. In some embodiments, the semiconductor device package 3 may include the TIM 24 and the heat sink 25 as shown in FIG. 2.

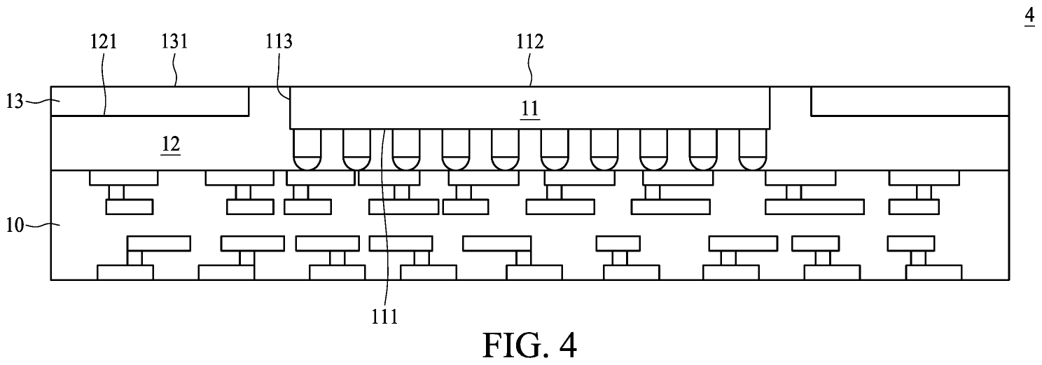

FIG. 4 illustrates a cross-sectional view of a semiconductor device package 4 in accordance with some embodiments of the present disclosure. The semiconductor device package 4 is similar to the semiconductor device package 1 in FIG. 1A except that the package body 12 in FIG. 4 is further disposed between the ring structure 13 and the lateral surface 113 of the electronic component 11. For example, the ring structure 13 is spaced apart from the lateral surface 113 of the electronic component 11 by the package body 12. For example, the lateral surface 113 of the electronic component 11 is fully covered by the package body 12. In some embodiments, the semiconductor device package 4 may include the TIM 24 and the heat sink 25 as shown in FIG. 2.

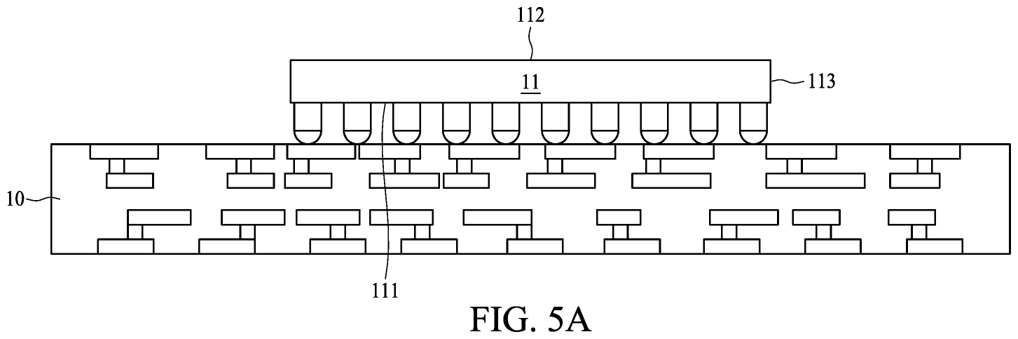

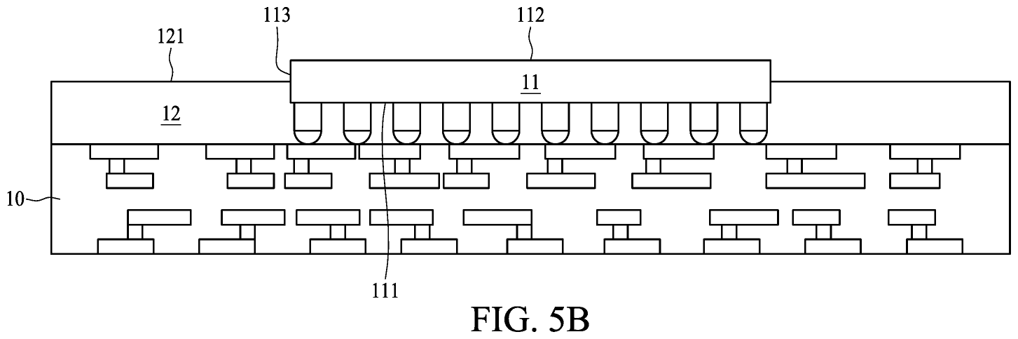

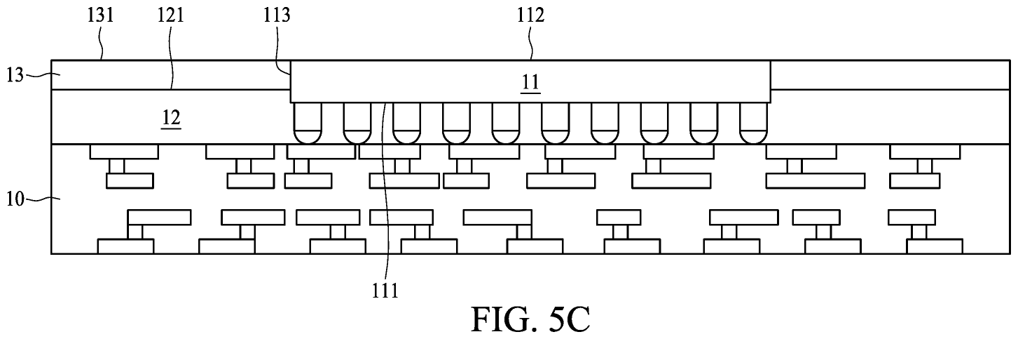

FIG. 5A, FIG. 5B and FIG. 5C illustrate cross-sectional views of a semiconductor device package at various stages of fabrication, in accordance with some embodiments of the present disclosure. Various figures have been simplified to better show aspects of the present disclosure. In some embodiments, the method illustrated in FIG. 5A, FIG. 5B and FIG. 5C can be used to manufacture the semiconductor device package 1 in FIG. 1A.

Referring to FIG. 5A, a carrier 10 is provided and an electronic component 11 is disposed on the carrier 10 with. An active surface 112 of the electronic component 11 faces the carrier 11 and electrically connected to the carrier 10 through electrical contacts (e.g., conductive bumps, copper pillars).

Referring to FIG. 5B, a package body 12 is formed on the carrier 10 and to surrounds the electronic component 11. A top surface 121 of the package body 12 is disposed at or adjacent to the lateral surface 113 of the electronic component 11. In other embodiments, the top surface 121 of the package body 12 may be substantially coplanar with the active surface 111 of the electronic component 11. In some embodiments, the package body 12 is in contact with the lateral surface 113 of the electronic component 11. In some embodiments, the package body 12 is formed by molding techniques, such as compression molding, selective molding or other suitable molding techniques.

Referring to FIG. 5C, a ring structure 13 is disposed on the top surface 121 of the package body 12. The ring structure 13 surrounds the lateral surface 113 of the electronic component 11 that exposed from the package body 12. In some embodiments, the ring structure 13 is in contact with the lateral surface 113 of the electronic component 11 that exposed from the package body 12. In other embodiments, the ring structure 13 may be spaced apart from the lateral surface 113 of the electronic component 11 that exposed from the package body 12. Then, a curing operation may be performed to cure or harden the package body 12 to form the semiconductor device package 1 as shown in FIG. 1A.

As used herein, the singular terms “a,” “an,” and “the” may include a plurality of referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” parallel can refer to a range of angular variation relative to 0° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°. For example, two surfaces can be deemed to be coplanar or substantially coplanar if a displacement between the two surfaces is no greater than 5 μm, no greater than 2 μm, no greater than 1 μm, or no greater than 0.5 μm.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations do not limit the present disclosure. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A semiconductor device package, comprising:
a carrier;
an electronic component disposed on the carrier, the electronic component having a side surface;
a package body disposed on the carrier, the package body exposing at least a portion of the side surface of the electronic component; and
a ring structure disposed on the package body and surrounding the portion of the side surface of the electronic component exposed from the package body.

2. The semiconductor device package of claim 1, wherein a tensile strength of the ring structure is greater than a tensile strength of the package body.

3. The semiconductor device package of claim 2, wherein the tensile strength of the ring structure is greater than 100 Mpa.

4. The semiconductor device package of claim 1, wherein an interface between the package body and the ring structure is located at the side surface of the electronic component.

5. The semiconductor device package of claim 1, wherein an interface between the package body and the ring structure is substantially coplanar with an active surface of the electronic component.

6. The semiconductor device package of claim 1, wherein the ring structure has a surface substantially coplanar with a backside surface of the electronic component.

7. The semiconductor device package of claim 1, wherein the ring structure is in contact with the portion of the side surface of the electronic component exposed from the package body.

8. The semiconductor device package of claim 1, wherein the ring structure is spaced apart from the portion of the side surface of the electronic component exposed from the package body.

9. The semiconductor device package of claim 8, wherein the package body is disposed between the ring structure and the portion of the side surface of the electronic component exposed from the package body.

10. A semiconductor device package, comprising:
a carrier;
an electronic component disposed on the carrier, the electronic component having a side surface;
a package body disposed on the carrier;
a ring structure disposed on the package body and surrounding the electronic component; and
a heat sink disposed on the ring structure and the electronic component.

11. The semiconductor device package of claim 10, wherein the heat sink is in contact with a backside surface of the electronic component and the ring structure.

12. The semiconductor device package of claim 10, wherein a tensile strength of the ring structure is greater than a tensile strength of the package body.

13. The semiconductor device package of claim 12, wherein the tensile strength of the ring structure is greater than 100 Mpa.

14. The semiconductor device package of claim 10, wherein an interface between the package body and the ring structure is located at a side surface of the electronic component.

15. The semiconductor device package of claim 10, wherein an interface between the package body and the ring structure is substantially coplanar with an active surface of the electronic component.

16. The semiconductor device package of claim 10, wherein the ring structure has a surface substantially coplanar with a backside surface of the electronic component.

17. The semiconductor device package of claim 10, wherein the ring structure is in contact with a side surface of the electronic component.

18. The semiconductor device package of claim 10, wherein the ring structure is spaced apart from a side surface of the electronic component.

19. The semiconductor device package of claim 18, wherein the package body is disposed between the ring structure and the side surface of the electronic component.

20. A method of manufacturing a semiconductor device package, comprising:
(a) providing a carrier;
(b) disposing an electronic component on the carrier, the electronic component having a side surface;
(c) forming a package body on the carrier, the package body exposing at least a portion of the side surface of the electronic component; and
(d) disposing a ring structure on the package body to surround the portion of the side surface of the electronic component exposed from the package body.

21. The method of claim 20, wherein operation (c) further comprising:
forming the package body on the carrier to cover the electronic component; and
removing a portion of the package body to expose at least a portion of the side surface of the electronic component.

22. The method of claim 20, wherein a tensile strength of the ring structure is greater than a tensile strength of the package body.

23. The method of claim 22, wherein the tensile strength of the ring structure is greater than 100 Mpa.

24. The method of claim 20, wherein the ring structure is in contact with the portion of the side surface of the electronic component exposed from the package body.

25. The method of claim 20, wherein the ring structure is spaced apart from the portion of the side surface of the electronic component exposed from the package body.

26. The method of claim 25, wherein the package body is disposed between the ring structure and the portion of the side surface of the electronic component exposed from the package body.
